(19) United States
(12) Patent Application Publication
(10) Pub. No.: US 2008/0258162 A1
(43) Pub. Date: Oct. 23, 2008

(54) PACKAGE FOR A HIGH-POWER LIGHT EMITTING DIODE

(76) Inventors: Chia-Yin KOUNG, Xindian City (TW); Wen LIN, Fuzhou City (CN)

Correspondence Address: Hershkovitz & Associates, LLC, 2845 Duke Street, Alexandria, VA, 22314, US

(21) Appl. No.: 12/062,002

(22) Filed: Apr. 3, 2008

(30) Foreign Application Priority Data
Apr. 17, 2007 (TW) 096113537

(51) Int. Cl. H01L 33/00

(52) U.S. Cl. 257/98; 257/E33.056

(57) ABSTRACT

A package for a high-power light emitting diode (LED) has a packaging substrate, at least one LED chip, at least one pair of conductive wires and an encapsulant. The packaging substrate has a reflective base with a recess, a dissipating board and at least one pair of electrodes. The electrodes and dissipating board are mounted in the reflective base and have upper surfaces. The LED chip is adhered to the dissipating board. The conductive wires connects electrodes of the LED chip and the electrodes. The encapsulant is transparent and fills the recess of the reflective base. Most heat from the LED chip is conducted via the dissipating board, thereby improving thermal conduction efficiency and allowing more powerful or numerous LED chips in the package. Therefore, the package provides different pass ways for conducting heat and electricity to improve heat conduction of the LED.

### BACKGROUND OF THE INVENTION

1. Field of Invention

The present invention relates to a package for a light emitting diode, and more particularly to a package for a high-power light emitting diode, which provides different pass ways for conducting heat and electricity. Therefore, the present invention improves heat conduction of the light emitting diode.

2. Description of the Related Art

With reference to FIG. 1, a conventional package for standard light emitting diodes (LED) has a lead frame, an LED chip (140), two electrically conductive wires (150) and resin (160). The lead frame has a reflective base (130) and two electrodes (120). The reflective base (130) has a top, a bottom, a front edge and an inverted trapezoidal recess. The recess is formed in the top of the reflective base (130) and has a surface (131) and a planar LED chip carrier. The planar LED chip carrier is mounted in the recess. The electrodes (120) are mounted through the reflective base (130), adjacent to each other and each electrode (120) has a proximal end (i.e. internal electrode) and a distal end (i.e. external electrode). The proximal end is mounted in the recess of the reflective base (130). The distal end is bent around and mounted on the bottom of the reflective base (130) and connects to a power source. The LED chip (140) is mounted on the planar LED chip carrier in the recess. The electrically conductive wires (150) connect electrically to the LED chip (140) and the electrodes (120). Resin (160) is formed in and fills the recess (131) to hold the LED chip (140) and the electrically conductive wires (150) securely.

Since the resin is thermally insulating, heat generated by the LED chip (140) and electrodes (120) can only be dissipated through the electrodes (120) that are very thin. Therefore, heat and electricity both pass through the electrodes, so the heat is conducted inefficiently. Moreover, the conventional package for standard light emitting diodes cannot be used for high-power light emitting diodes that generate more heat than standard light emitting diodes.

To overcome the shortcomings, the present invention provides a package for high-power light emitting diodes to mitigate or obviate the aforementioned.

### SUMMARY OF THE INVENTION

The primary objective of the present invention is to provide a package for a high-power light emitting diode (LED), which provides different pass ways for conducting heat and electricity.

To achieve the objective, the package for a high power LED in accordance with the present invention comprises a packaging substrate, at least one LED chip, at least one pair of conductive wires and an encapsulant. The packaging substrate has a reflective base, a dissipating board and at least one pair of electrodes. The reflective base is electrically insulating and has a top and a recess. The recess is formed in the top of the reflective base. The dissipating board is made of metal, is mounted on the reflective base and has an upper surface adjacent to the recess. Each pair of electrodes is metal and is mounted on the reflective base and has upper surfaces. Each LED chip connects electrically to one pair of electrodes and is adhered to the dissipating board. Each conductive wire connects electrically to one LED chip and one electrode. The encapsulant is transparent and is formed in and fills the recess of the reflective base.

The package for high-power LED in addition to the electrodes, further comprises the dissipating board therefore, most heat from each LED chip conduct via the dissipating board thereby improving thermal conduction efficiency and allowing more powerful and numerous LED's to operate per package so increasing applications of LED's. Therefore, the present invention provides different pass ways for conducting heat and electricity to improve heat conduction of the LED.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional side view of a conventional package for a standard light emitting diode in accordance with the prior art;

FIG. 2A is a cross sectional side view of a package for a high-power light emitting diode in accordance with the present invention;

FIG. 2B is an exploded perspective view of the package for the high-power light emitting diode in FIG. 2A;

FIG. 2C is a perspective view of the package for the high-power light emitting diode in FIG. 2A, shown with a lens covering a recess;

FIG. 2D is a cross sectional side view of the package for the high-power light emitting diode in FIG. 2A showing fluorescer formed in and filling a recess of a reflective base;

FIG. 3A is a perspective view of the package for the high-power light emitting diode in FIG. 2A, shown with two LED chips;

FIG. 3D is a perspective view of the package for the high-power light emitting diode in FIG. 2A, shown with three LED chips; and

FIGS. 4A to 4F are perspective views of steps of a packaging method to manufacture a package for a high-power light emitting diode in accordance with the present invention.

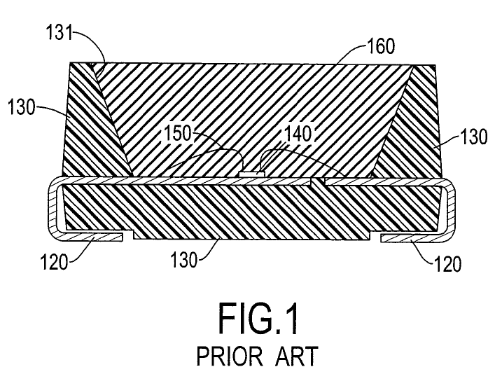

### DETAILED DESCRIPTION OF THE INVENTION

A package for a high-power light emitting diode (LED) comprising at least one LED chip, a packaging substrate, multiple conductive wires and an encapsulant. The packaging substrate has a dissipating board being metal, multiple electrodes being metal and a reflective base being made of insulating materials. The insulating materials are filled between the dissipating board and the electrodes to allow the dissipating board to be insulated from the electrodes and are molded upon the dissipating board and electrodes to form the reflective base with a recess to expose an upper surface of the dissipating board for attaching the LED chip on the dissipating board and at least a portion of an upper surface of the electrodes for wire-bonding the LED chip to the electrodes. The conductive wires connects electrodes of the LED chip and the electrodes. The encapsulant is pervious to light and is filled in the recess of the base to protect the LED chips and the conductive wires.

Preferably, the dissipating board of the packaging substrate is mounted in a center of a bottom of the packaging substrate and allows the upper surface of the dissipating board to be exposed upward from an upper surface of the bottom of the packaging substrate and a lower surface of the dissipating board to be exposed downward from a lower surface of the bottom of the packaging substrate.

Preferably, the electrodes of the packaging substrate are mounted around the dissipating board and allows the upper surfaces of the electrodes to be exposed upward from an upper surface of a bottom of the packaging substrate and lower surfaces of the electrodes to be exposed downward from a lower surface of a bottom of the packaging substrate.

Preferably, the reflective base is made of insulating materials that are able to reflect light.

Preferably, the dissipating board further has a chip-bonding recess for being filled with fluorescer, which is formed in the upper surface of the dissipating board.

Preferably, the encapsulant comprises fluorescer.

Preferably, the package for the high-power LED of the present invention further has an optical lens being mounted on the reflective base to cover the reflective base.

The present invention will become detailed from the following description, taken with the accompanying drawings.

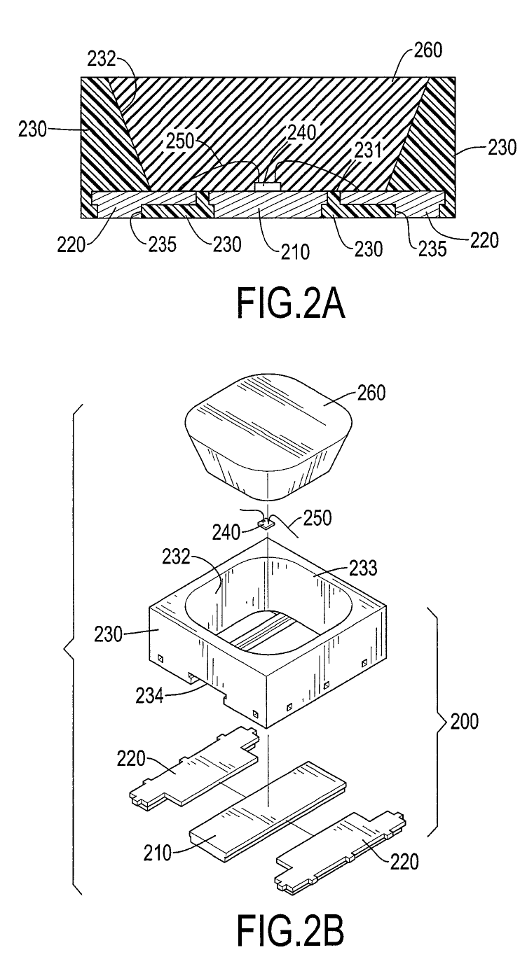

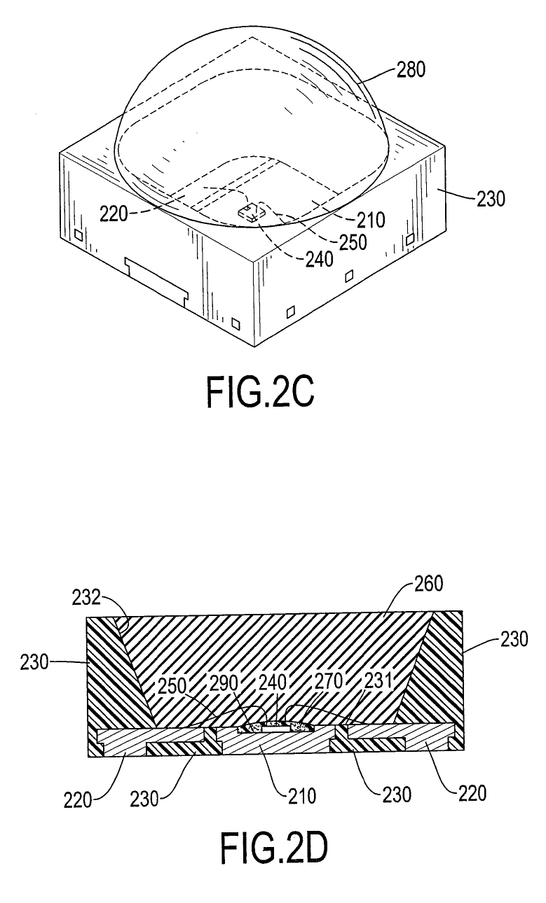

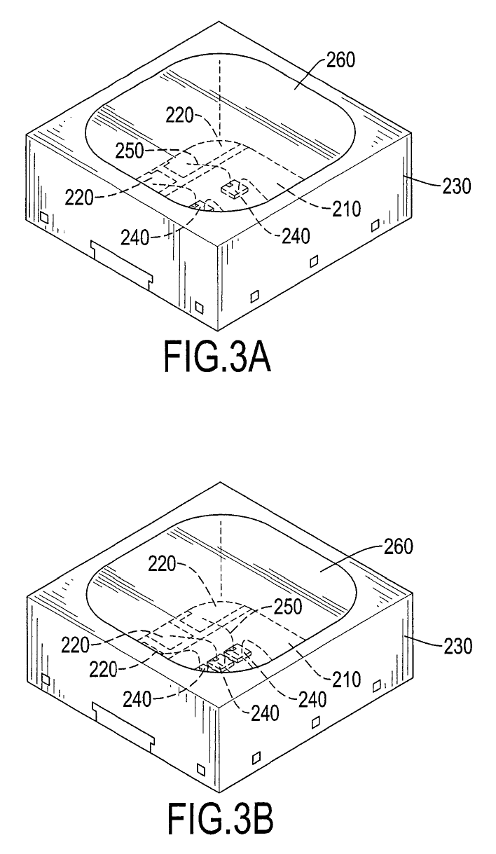

With reference to FIGS. 2A, 2B, 3A and 3B, each package for a high-power light emitting diode (LED) in accordance with the present invention, manufactured by the packaging method outlined above, has a substrate (200), at least one LED chip (240), at least one pair of conductive wires (250) and an encapsulant (260).

The substrate (200) has a reflective base (230), a dissipating board (210) and at least one pair of electrodes (220).

The reflective base (230) may be reflective, is electrically insulating and may be resin or ceramic and has a top, a recess (233) and a bottom. The recess (233) is formed in the top of the reflective base (230) and has a reflective bottom (231) and a reflective sidewall (232). The bottom of the reflective base (230) has a central slot (234) [for engaging the dissipating board (210)] and at least one pair of electrode mounts (235). The central slot (234) is defined through the bottom of the reflective base (230), communicates with the recess (233) and has a shoulder. Each pair of the electrode mounts (235) is formed on opposite sides of the central slot (234) and each electrode mount (235) has an electrode slot formed through the bottom of the reflective base (230) and communicating with the recess (233) and the electrode mount (235).

With further reference to FIG. 2C, each package for a high-power LED further has an optical lens (280). The optical lens (280) is mounted on the reflective base (230) to cover the reflective base (230) for adjusting a light path.

With further reference to FIG. 2D, the dissipating board (210) is made of metal, is mounted on the bottom of the reflective base (230), may correspond to and be mounted in the central slot (234) and has an upper surface and a chip-bonding recess (290). The upper surface of the dissipating board (210) is adjacent to the recess (233). The chip-bonding recess (290) is formed in the upper surface of the dissipating board (210) and is filled with fluorescer (270). The fluorescer (270) allows light produced by the package to be tailored to different colors.

Each pair of the electrodes (220) are metal, are mounted on the bottom surface of the reflective base (230), may correspond to and be mounted in one pair of electrode mounts (235) and are separated by a gap from the dissipating board (210) has an upper surface. The upper surface of the electrodes (220) are adjacent to the recess (233). Each LED chip (240) connects electrically to one pair of the electrodes (220) and is adhered to the dissipating board (210) and may be mounted in the chip-bonding recess (290), may be surrounded by the fluorescer (270) to excite the fluorescer (270) and has two terminals. When the LED chip (240) is blue LED, the fluorescent agent (270) will be excited to generate yellow light. A balanced mixing of yellow and blue lights results in an appearance of white light. Each LED chip (240) has two terminals. When there are more than one LED chip (240) in the recess (233), the LED chips (240) may have a single color or different colors. In one aspect of the present invention, there are three LED chips (240) that emit respectively red light, green light and blue light. A balanced mixing of those lights emitted from the LED chips (240) results in an appearance of white light.

Techniques for mixing lights and utilizing flourescers (270) are well known by those possessing ordinary skill in the art. Therefore, a number of LED chips (240) is not limited in the present invention.

Light emitted by the package can be tailored using the fluorescer (270) or multiple lights emitting different wavelengths that are mixed, techniques for mixing lights and utilizing fluorescer (270) is well known by those possessing ordinary skill in the art. Therefore, a number of LED chips (240) is not limited in the present invention.

Each conductive wire (250) connects electrically one terminal of one LED chip (240) to one electrode of one pair of electrodes (220).

The encapsulant (260) is pervious to light, preferably is transparent, may be transparent resin, transparent resin with fluorescer or the like and is formed in and fills the recess (233) of the substrate (200) to hold and protect each LED chip (240) and each pair of conductive wires.

The package for high-power LED of the present invention in addition to the electrodes (220) further comprises the dissipating board (210) therefore, heat from each LED chip (240) is mainly conducted via the dissipating board (210) thereby improving thermal conduction efficiency and allowing more powerful and numerous LED chips to operate per package so increasing applications of LEDs.

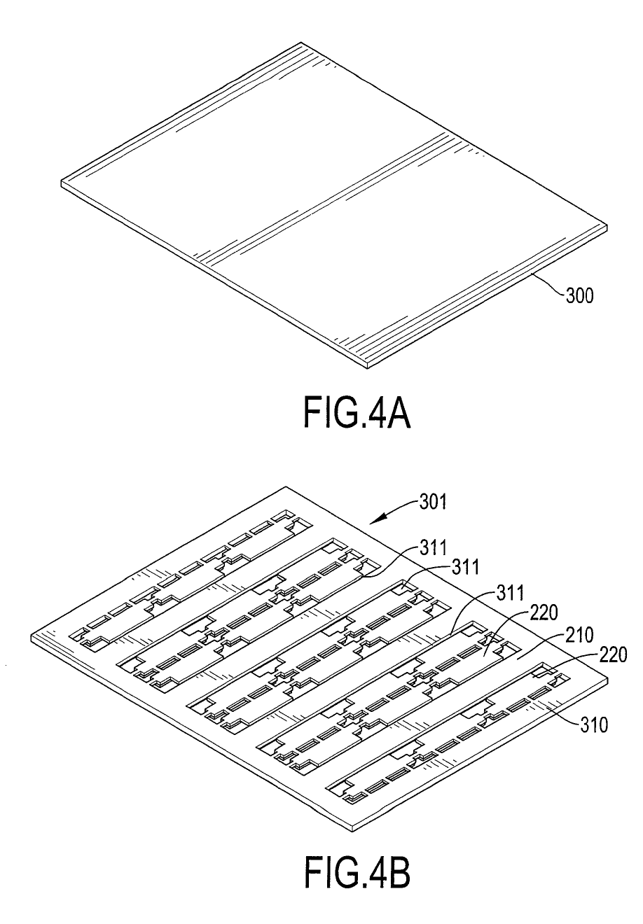

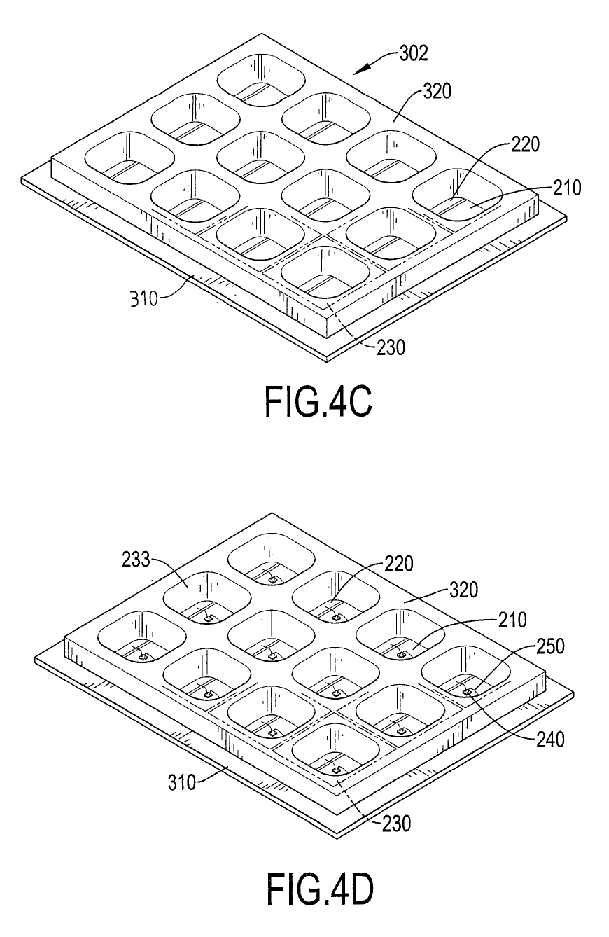

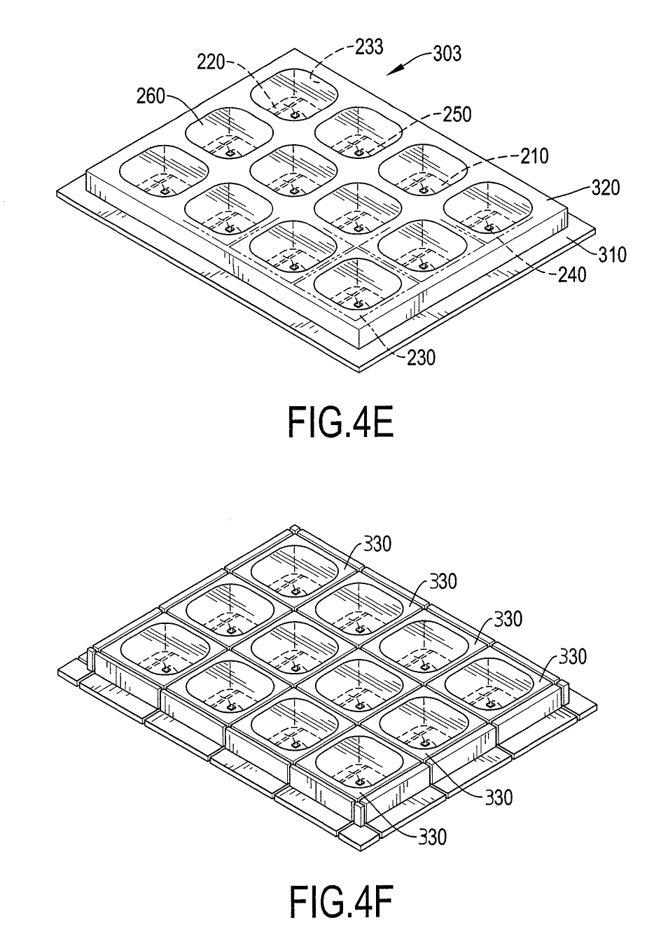

With further reference to FIGS. 2B and 4A to 4F, a packaging method to manufacture quantities of the high-power LED packages in accordance with the present invention comprises steps of: (a) obtaining a metal board (300), (b) treating the metal board (300) to form an after-treating metal board (301), (c) molding a cell matrix (320) with multiple reflective bases (230) on the after-treating metal board (301) to form a after-molding board (302), (d) attaching LED chips (240) onto the dissipating boards (210) and bonding conductive wires (250) in each corresponding reflective base (230) of the cell matrix (320) of the after-molding board (302), (e) encapsulating the LED chips (240) and conductive wires (250) in the reflective base of the cell matrix (320) to form a after-packaging board (303) and (f) cutting off the after-packaging board (303) to form multiple individual high-power LED packages (330).

The step of (a) obtaining a metal board (300) comprises obtaining a metal board (300) (as shown in FIG. 4A).

The step of (b) treating the metal board (300) comprises treating the metal board (300) using etching or machining (such as punching) to form an after-treating metal board (301) with a margin (310) and multiple units (as shown in FIG. 4B). The after-treating metal board (301) comprises the margin (310) and multiple units to connect integrally to each other. Each unit has at least one pair of electrodes (220), a dissipating board (210) and multiple gaps (311). Each electrode (220) connects to an electrode (220) of an adjacent unit. The electrode (220) adjacent to the margin (310) further connect to the margin (310). Each dissipating board (210) is surrounded by at least one pair of the electrodes (220) and connects to a dissipating board (210) of an adjacent unit. The dissipating boards (210) adjacent to the margin (310) further connect to the margin (310). The gaps (311) are formed between each one pair of the electrodes (220) and the dissipating board (210).

The step of (c) molding the cell matrix (320) comprises forming a cell matrix (320) on the after-treating metal board (301) and filling the gaps (311) with an insulating material simultaneously to form an after-molding board (302) with multiple substrates (200). The step of (c) molding the cell matrix (320) may be using injection-compression molding (as shown in FIG. 4C). The insulating material may be resin, ceramic or the like. The cell matrix (320) has multiple reflective bases (230). The reflective bases (230) correspond respectively to the units. Each substrate (200) comprises at least one pair of electrodes (220), a dissipating board (210) and a reflective base (230). Each reflective base (230) has a recess (233). At least a portion of an upper surface of the dissipating board (210) and at least a portion of an upper surface of the electrode (220) are exposed to the recess (233) and at least a portion of an lower surface of the dissipating board (210) and at least a portion of an lower surface of the electrodes (220) are exposed from a lower surface of the reflective base (230).

The step of (d) attaching LED chips (240) and bonding a pair of conductive wires (250) comprises wire bonding at least one LED chip (240) onto the dissipating boards (210) of each substrate (200) to connect electrically to the electrodes (220) by the conductive wires (250) (as shown in FIG. 4D).

The step of (e) encapsulating the LED chips (240) and conductive wires (250) comprises filling the recesses (233) in the reflective bases (230) of the cell matrix (320) with an encapsulant (260) that is pervious to light to form an after-packaging board (303) (as shown in FIG. 4E).

The step of (f) cutting off the after-packaging board (303) comprises separating the reflective bases (230) of the cell matrix (320) and the units of the after-treating metal board (301) to obtain multiple individual packages (330) for high-power LEDs (as shown in FIG. 4F).

According to the method of the present invention, multiple LED substrates (200) can be formed on the after-treating metal board (301) by once-molding technique, which accelerates to proceed the step of (d) to (f). Therefore, the present invention provides a packaging method that can save time and cost.

For further increasing reflectivity of the substrate (200), the dissipating board (210) and the electrodes (220) of each substrate (200) may be coated or plated with a reflective coating after the step of (b) and before the step of (c) or after the step of (c) and before the step of (d). The dissipating board (210) and the electrodes (220) may be plated with silver coating or other conductive materials.

The recess (233) may be coated or plated with a reflective coating after the step of (c) and before the step of (d). The reflective sidewall (232) of the recess (233) may be plated with aluminum coating, silver coating or the like.

The package for high-power LED of the present invention in addition to the electrodes (220) further comprises the dissipating board (210) therefore, heat from each LED chip (240) is mainly conducted via the dissipating board (210) thereby improving thermal conduction efficiency and allowing more powerful and numerous LED chips to operate per package so increasing applications of LEDs.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A package for a high-power light emitting diode (LED) comprising:
at least one LED chip;
a packaging substrate comprising
a dissipating board being metal;
multiple electrodes being metal;
a reflective base being made of insulating materials that are filled between the dissipating board and the electrodes to allow the dissipating board to be insulated from the electrodes and are molded upon the dissipating board and electrodes to form the reflective base with a recess to expose an upper surface of the dissipating board for attaching the LED chip on the dissipating board and an upper surface of the electrodes for wire-bonding the LED chip to the electrodes;
multiple conductive wires connecting electrodes of the LED chip and the electrodes; and
an encapsulant being pervious to light and being filled in the recess of the reflective base to protect the LED chips and the conductive wires.

2. The package for a high-power LED as claimed in claim 1, wherein the dissipating board of the packaging substrate is mounted in a center of a bottom of the packaging substrate and allows the upper surface of the dissipating board to be exposed upward from an upper surface of the bottom of the packaging substrate and a lower surface of the dissipating board to be exposed downward from a lower surface of the bottom of the packaging substrate.

3. The package for a high-power LED as claimed in claim 1, wherein the electrodes of the packaging substrate are mounted around the dissipating board and allows the upper surfaces of the electrodes to be exposed upward from an upper surface of a bottom of the packaging substrate and lower surfaces of the electrodes to be exposed downward from a lower surface of a bottom of the packaging substrate.

4. The package for a high-power LED as claimed in claim 2, wherein the electrodes of the packaging substrate are mounted around the dissipating board and allows the upper surfaces of the electrodes to be exposed upward from an upper surface of a bottom of the packaging substrate and lower surfaces of the electrodes to be exposed downward from a lower surface of a bottom of the packaging substrate.

5. The package for a high-power LED as claimed in claim 1, wherein the reflective base is made of insulating materials that are able to reflect light.

6. The package for a high-power LED as claimed in claim 4, wherein the reflective base is made of insulating materials that are able to reflect light.

7. The package for a high-power LED as claimed in claim 2, wherein the dissipating board further has a chip-bonding recess for being filled with fluorescer, which is formed in the upper surface of the dissipating board.

8. The package for a high-power LED as claimed in claim 4, wherein the dissipating board further has a chip-bonding recess for being filled with fluorescer, which is formed in the upper surface of the dissipating board.

9. The package for a high-power LED as claimed in claim 1, wherein the encapsulant has fluorescer.

10. The package for a high-power LED as claimed in claim 2, wherein the encapsulant has fluorescer.

11. The package for a high-power LED as claimed in claim 3, wherein the encapsulant has fluorescer.

12. The package for a high-power LED as claimed in claim 4, wherein the encapsulant has fluorescer.

13. The package for a high-power LED as claimed in claim 1 further has an optical lens being mounted on the reflective base to cover the reflective base.

14. The package for a high-power LED as claimed in claim 2 further has an optical lens being mounted on the reflective base to cover the reflective base.

15. The package for a high-power LED as claimed in claim 3 further has an optical lens being mounted on the reflective base to cover the reflective base.

16. The package for a high-power LED as claimed in claim 4 further has an optical lens being mounted on the reflective base to cover the reflective base.

17. The package for a high-power LED as claimed in claim 5 further has an optical lens being mounted on the reflective base to cover the reflective base.

18. The package for a high-power LED as claimed in claim 6 further has an optical lens being mounted on the reflective base to cover the reflective base.

19. The package for a high-power LED as claimed in claim 7 further has an optical lens being mounted on the reflective base to cover the reflective base.

20. The package for a high-power LED as claimed in claim 8 further has an optical lens being mounted on the reflective base to cover the reflective base.
